(19) United States
(12) Patent Application Publication
(10) Pub. No.: US 2015/0263196 A1
(43) Pub. Date: Sep. 17, 2015

(54) PHOTOVOLTAIC MODULE AND PROCESS FOR MANUFACTURE THEREOF

(71) Applicant: E I DU PONT DE NEMOURS AND COMPANY, Wilmington (DE)

(72) Inventors: ANDREAS MEISEL, San Jose, CA (US); PETROS DAFNIOTIS, GENEVA (CH); RAUL O CORTEZ, SAN JOSE, CA (US)

(21) Appl. No.: 14/618,327

(22) Filed: Feb. 10, 2015

Related U.S. Application Data
(60) Provisional application No. 61/952,473, filed on Mar. 13, 2014.

(51) Int. Cl. H01L 31/0224; H01L 31/18; H01L 31/049

(52) U.S. Cl. CPC H01L 31/022441; H01L 31/049; H01L 31/18

(57) ABSTRACT

A photovoltaic module has a plurality of interconnected polymer sockets that have accepted and electrically connected a plurality of back-contact photovoltaic cells each having at least one set of linearly arranged back face emitter contacts and at least one set of linearly arranged back face collector contacts. A process for manufacturing such a photovoltaic module is also provided.

### FIELD OF THE INVENTION

The present invention relates to a photovoltaic module comprising a plurality of concatenated polymer sockets, each polymer socket having accepted and electrically connected a back-contact photovoltaic cell. The invention relates also to a process for the manufacture of such a photovoltaic module.

### BACKGROUND OF THE INVENTION

Photovoltaic cells, sometimes called soar cells or photoactive cells, can convert light, such as sunlight, into electrical energy.

In practice, a plurality of photovoltaic cells is electrically connected together in series or in parallel to form an array of photovoltaic cells which can be incorporated into a photovoltaic module. In order to increase the voltage delivered by individual photoactive cells to a suitable level, the cells are conventionally connected in series. A serial connection between the cells of a module can be achieved by connecting the emitter contact of one photovoltaic cell to the collector contact of the next (adjacent) cell, usually by soldering an electrical conductor such as wire, tape or ribbon to the contacts of adjacent cells.

In most of today's photovoltaic modules, the photovoltaic cells that convert light into electrical energy are cells in which the emitter contacts and collector contacts are located on opposite sides of the cells. The emitter contacts, often in shape of an H-type pattern, are located on the front surface, i.e. the surface exposed to the sunlight, whereas the collector contacts are on the back side. FIG. 1A shows the front face of an H-type photovoltaic cell E having two emitter contacts (D1, D2), also known as emitter bus bars. FIG. 1B shows the back face of an H-type photovoltaic cell E having two collector contacts (F1, F1), also known as collector bus bars. A skilled person will recognize that emitter contacts and collector contacts are of opposite polarity.

The electrical conductors connecting two cells are soldered to the emitter and collector contacts such that the front emitter contacts of one photovoltaic cell are connected with one or more back collector contacts of the adjacent photovoltaic cell. On an industrial scale, the electrical conductors are applied to the cell contacts by way of automated soldering equipment (so-called “tabber-stringer”).

However, the electrical conductors cover a portion of the available photovoltaic surface of the cell, which in turn reduces the amount of electrical energy that can be produced by the cell.

New cell types have been developed in which the emitter contacts have been moved from the front face to the back face of the photovoltaic cell in order to free up an additional portion of front surface and increase the amount of electrical energy that can be produced by the cell. Such photovoltaic cells, in which both emitter and collector contacts are located on the back side of the cell, are known under the common designation “back-contact (BC) cells”, which designation encompasses emitter wrap-through (EWT) cells, metallization wrap-through (MI/VT) cells, back-junction (BJ) cells, and interdigitated back-contact (IBC) cells.

Moving from traditional H-type cells having front emitter contacts to back-contact cells having back emitter contacts requires changes in the structure of the photovoltaic module itself, such as for example a complete redesign of the electrical connections between the cells. Concurrently, these structural changes in the photovoltaic module also require a redesign of the manufacturing equipment as well as changes in the module manufacturing method.

WO2006/123938 describes a method of contacting BC cells by tabbing and stringing. However, the proposed method requires the use of extensive amounts of an insulating material, which is economically discouraging. Furthermore, applying significant amounts of insulating material as well as the electrical conductors on the rear side of a cell creates local unevenness that will warp the cell during the lamination step of module production. The warpage induces mechanical strains in the cell, which results in a lessened degree of efficiency, and also results in the formation of cracks.

The above described changes in cell technology make the purchase of new manufacturing equipment inevitable for a module manufacturer desiring to use back-contact cells, which presents a considerable economic hurdle for the adoption of back-contact cells in photovoltaic modules. It would therefore be desirable to provide for a means that allows the manufacturing of photovoltaic modules incorporating back-contact cells, but without the need of entirely replacing or considerably altering existing tabber-stringer manufacturing equipment and thus make the change more economically feasible.

### SUMMARY OF THE INVENTION

The present invention provides for a photovoltaic module comprising a front sheet, a front encapsulant layer, a plurality of back-contact photovoltaic cells each having a front face and a back face, each back-contact photovoltaic cell having on its back face at least one set of linearly arranged back face emitter contacts and at least one set of linearly arranged back face collector contacts. Each of the back-contact photovoltaic cells is adhered to the front encapsulant layer. A plurality of concatenated polymer sockets are arranged in one or more rows. Each polymer socket has accepted and electrically connected one of the back-contact photovoltaic cells. A back sheet is adhered over said plurality of concatenated polymer sockets.

Each polymer socket comprises a planar, electrically insulating polymer substrate. The polymer substrate has a front face and back face on opposite sides of the substrate. The front face is on the side of the substrate on which the back-contact photovoltaic cell is accepted by the polymer socket. The polymer substrate has a shape, length and width that substantially corresponds to the shape, length and width of the back-contact photovoltaic cell accepted by the socket. The polymer socket has columns of linearly arranged perforations coinciding with and aligned over at least one set of linearly arranged back face emitter contacts and at least one set of linearly arranged back face collector contacts of the back-contact photovoltaic cell accepted by the polymer socket.

A plurality of electrical conductors are positioned on the back face of the polymer substrate. Each of said conductors are collinear with a column of the perforations in the polymer substrate and coincide with the set of linearly arranged back face emitter contacts or the set of linearly arranged back face collector contacts of the back-contact photovoltaic cell accepted and electrically connected by the socket. The electrical conductors are each connected to the set of emitter contacts or the set of collector contacts of the back-contact photovoltaic cell accepted and electrically connected by the socket. The sockets are arranged in rows, and the electrical conductors of each polymer socket that are connected to emitter contacts of the back-contact photovoltaic cell accepted by the socket are electrically connected to an electrical conductor of an adjacent socket in the row of sockets which electrical conductor of the adjacent socket is connected to collector contacts of the back-contact photovoltaic cell accepted by the adjacent socket.

### BRIEF DESCRIPTION OF THE DRAWINGS

FIG. 1A shows the front face of an H-type photovoltaic cell.

FIG. 1B shows the back face of an H-type photovoltaic cell.

FIG. 2 shows the front face of a MWT back-contact photovoltaic cell.

FIG. 3 shows the back face of a MWT back-contact photovoltaic cell.

FIG. 4 shows the back face of an IBC back-contact photovoltaic cell.

FIG. 5 shows an exploded view of a plurality of back-contact photovoltaic cells and a plurality of polymeric sockets electrically interconnected to form a concatenation of interconnected polymer sockets and photovoltaic cells according to one embodiment.

FIG. 6 shows a cross-sectional side view of a section of the electrically insulating polymer socket substrate on the back face of a back-contact photovoltaic cell.

FIG. 7 shows an exploded view of a plurality of back-contact photovoltaic cells and a plurality of polymeric sockets electrically interconnected to form a concatenation of interconnected polymer sockets and photovoltaic cells according to another embodiment.

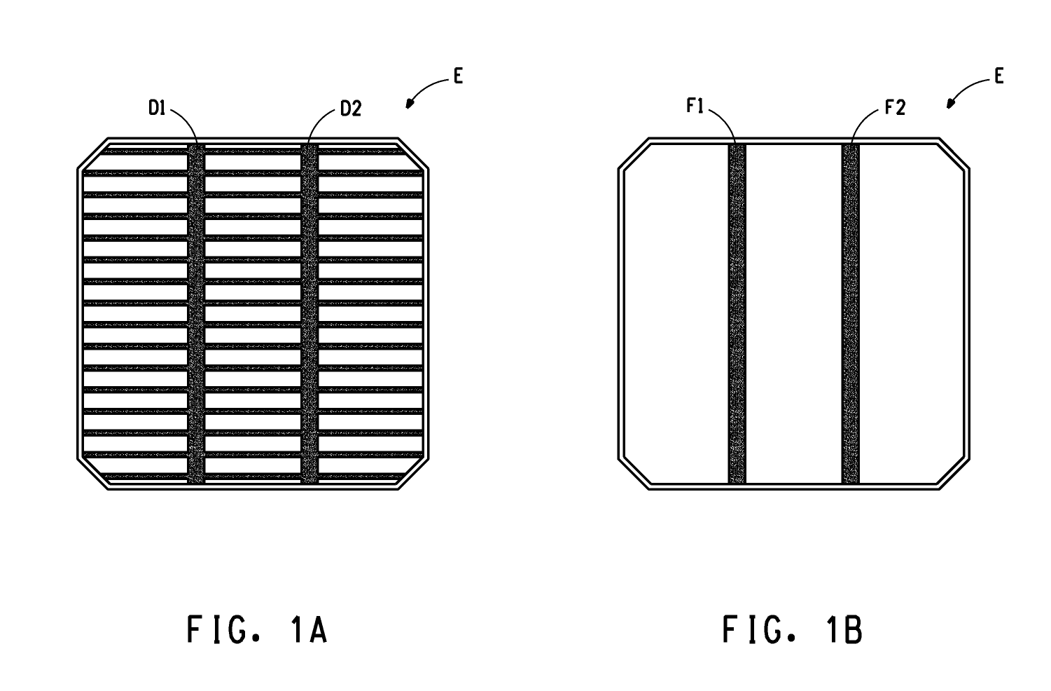

### DETAILED DESCRIPTION

For the purpose of the present disclosure, the term “back face” or “back” denotes the surface of a photovoltaic cell in a photovoltaic module, or of any other planar element in a photovoltaic module, such as in particular the polymer sockets of the photovoltaic module of the present invention, which faces away from incident light, i.e. which faces towards the back sheet of the photovoltaic module.

For the purpose of the present disclosure, the term “front face” or “front” denotes the surface of a photovoltaic cell in a photovoltaic module, or of any other planar element in a photovoltaic module, such as in particular the polymer sockets of the photovoltaic module of the present invention, which faces towards incident light, i.e. which faces away from the back sheet and towards the front sheet of the photovoltaic module.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electrical energy.

For the purpose of the present disclosure, the terms “photovoltaic cell” or “photoactive cell” means an electronic device that can convert electromagnetic radiation (e.g., light) into an electrical signal. A photovoltaic cell includes a photoactive material layer that may be an organic or inorganic semiconductor material that is capable of absorbing radiation and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (CIGS) photoactive layers.

For the purpose of the present disclosure, the term “back-contact cells” refers to photovoltaic cells in which both emitter and collector contacts are located on the back side of the cell, and includes metallization wrap-through (MWT) cells, back-junction (BJ) cells, interdigitated back-contact (IBC) cells and emitter wrap-through (EWT) cells.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical stress.

For the purpose of the present disclosure, the term “front encapsulant layer” refers to an encapsulant layer that is located between the front face of a photoactive cell and the front sheet of the module.

For the purpose of the present disclosure, the term “back encapsulant layer” refers to an encapsulant layer that is located between the back face of a photoactive cell and the back sheet of the module.

For the purpose of the present disclosure, the term “ionomer” means and denotes a thermoplastic resin containing both covalent and ionic bonds derivable from ethylene copolymers. Ionomers may be obtained by partial neutralization of ethylene-methacrylic acid copolymers or ethylene-acrylic acid copolymers with inorganic bases having cations of elements from Groups I, II, or III of the Periodic table, notably, sodium, aluminum, lithium, magnesium, and barium may be used, or transition metals such as zinc. The term “ionomer” and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn Ionomer Resins”, Polyelectrolytes, 1976, C, 177-197.

For the purpose of the present disclosure, the term “emitter contact” means and denotes an electrical contact connecting the emitter of a photovoltaic cell to an electrical conductor. In the case of MWT back-contact photovoltaic cells, the emitter contacts are the so-called via contacts located on the back face of the cell, In the case of an IBC back-contact cell, the emitter contacts are metal contacts connecting the emitter region of the IBC cell.

For the purpose of the present disclosure, the term “collector contact” means and denotes an electrical contact connecting the collector of a photovoltaic cell to an electrical conductor. In the case of a back-contact MWT cells, the collector contacts are located in lines on the back face of the cell. In the case of IBC back-contact cells, the collector contacts are metal contacts connecting the collector region of the IBC cell.

For the purpose of the present disclosure, the term “concatenation” refers to an unbranched, row-like assembly of two or more elements.

For the purpose of the present disclosure, the term “collinear” refers to a collinear relationship, when viewed along the direction normal to the plane defined by the polymer substrate of a polymer socket as described herein.

The present invention provides for a photovoltaic module comprising a front sheet, a front encapsulant layer, a plurality of back-contact photovoltaic cells, a plurality of concatenated polymer sockets, each polymer socket having accepted and electrically connected a back-contact photovoltaic cell, an optional back encapsulant layer, and a back sheet. The back-contact photovoltaic cells are preferably crystalline silicon solar cells. Each back-contact photovoltaic cell of the photovoltaic module is accepted by a separate socket. Each back-contact photovoltaic cell has at least one set of back face emitter contacts and at least one set of back face collector contacts on the back face of the back-contact cell. The back face emitter contacts are linearly arranged in a preferred embodiment and the back face collector contacts are linearly arranged in a preferred embodiment. Each polymer socket comprises a planar, electrically insulating polymer substrate that has columns of perforations coinciding with and aligned over the linearly arranged back face emitter contacts and the linearly arranged back face collector contacts of a back contact solar cell accepted on the front face of the socket. A plurality of electrical conductors are positioned on the back face of each polymer socket. The electrical conductors are collinear with the columns of perforations in the planar substrate of the socket. Each of the electrical conductors is connected to either a plurality of the emitter contacts or a plurality of collector contacts through the perforations in the polymer substrate. In one embodiment, the electrical conductors are adhered to the back face of the planar polymer socket substrate. In another embodiment, the electrical conductors are held in place solely by their connection to the emitter or collector contacts on the back face of the back-contact solar cell accepted in the socket. Except for the first and last photovoltaic cells in each series of electrically connected cells, the electrical conductors on the back face of each socket connected to cell contacts of one polarity on the back of a solar cell are electrically connected to one or more conductors on an adjacent socket which conductors are electrically connected to back-contacts of opposite polarity on the adjacent photovoltaic cell accepted by the adjacent socket. The back-contact photovoltaic cells accepted and electrically connected by adjacent polymer sockets may be rotated by 180° with respect to each other in certain preferred embodiments such as certain modules comprising MWT cells.

For the purpose of the present disclosure, the term “linearly arranged contacts” refers to a plurality of the same type of contacts (either collector or emitter) arranged in-line.

The polymer sockets for accepting and electrically connecting a back-contact photovoltaic cells have substantially similar height and width as the back-contact cells accepted by the sockets. Making the sockets the same size as the solar cells to be accepted by the sockets makes it possible to use existing photovoltaic cell tabber-stringer equipment to interconnect the sockets. The shape and size of the planar, electrically insulating polymer substrate of each polymer socket corresponds to or extends slightly beyond the length and width of the back-contact photovoltaic cell accepted and electrically connected by the polymer socket. Preferably each socket substrate is no more than 10 mm longer or wider than the corresponding back-contact cell accepted by the socket, and more preferably no more than 5 mm longer and wider than the corresponding back contact cell accepted by the socket. The length and width of the planar, electrically insulating polymer substrate of each socket may extend from 0.5 mm to 5 mm beyond the edges of the back-contact photovoltaic cell to be accepted and electrically connected by the polymer socket. In one preferred embodiment, the edges of the polymer substrate of each socket extend no more than 2 mm beyond the edges of the photovoltaic cell accepted by each socket. In another embodiment, the length and width of each polymer substrate of each socket are substantially the same as the length and width of the photovoltaic cell accepted by the socket. The thickness of the polymer substrates of the sockets may be of from 40 μm to 500 μm, more preferably of from 50 μm to 200 μm. The use of sockets of substantially the same or similar height and width as the photovoltaic cells of the module has been found to have the advantage that the sockets integrate well with existing photovoltaic module manufacturing equipment, and makes it possible to readily position the front face of the sockets on the back face of the corresponding back-contact photovoltaic cells with the perforations of the sockets oriented and aligned over the contacts on the back face of the photovoltaic cells.

The planar, electrically insulating polymer substrate of the polymer socket may comprise Tedlar® PVF, PET, laminates such as TPE (Tedlar® PVF/PET/EVA) laminate, TE (Tedlar® PVF/EVA) laminate, polycarbonate, acrylate polymer such as polymethylmethacrylate (PMMA) material, or a more flexible material, such as a fluoropolymer like for example polyvinyl fluoride (PVF), a polyvinylidene fluoride (PVDF), an ethylene tetrafluorethylene (ETFE) polymer, a perfluoroalkoxy vinyl polymer (PFA), an FEP (fluorinated ethylene propylene) copolymer of tetrafluoroethylene (TFE) and hexafluoropropylene (HFP), or a combination thereof. One preferred polymer for the socket substrate is a material that exhibits the behavior of an elastomeric thermoplastic polymer. The planar polymer socket substrate may comprises or consist of at an elastomeric thermoplastic polymer. Suitable elastomeric thermoplastic polymers may be chosen among polymers having a melting temperature in excess of the temperature applied in the lamination process step of the photovoltaic module manufacturing process. The elastomeric thermoplastic polymers may be chosen, for example among styrenic block copolymers, polyolefin blends, elastomeric alloys such as engineering thermoplastic vulcanizates (ETPVs), ionomers, thermoplastic polyurethanes, thermoplastic copolyesters and thermoplastic polyamides. Preferably, the planar, electrically insulating polymer substrate comprises a styrenic block copolymer such as styrene-butadiene-styrene block copolymer (SBS), styrene-isoprene-styrene block copolymer (SIS), styrene-ethylene/butylene-styrene block copolymer (SEBS) and styrene-ethylene/propylene-styrene block copolymer (SEPS) or thermoplastic copolyester such as polyester-polyether copolymer.

The planar, electrically insulating polymer substrate of the polymer socket may be obtainable, for example, by injection molding the polymer (e.g. elastomeric thermoplastic polymer) into the desired shape, by cutting out the desired shape from a sheet of polymer (e.g. elastomeric thermoplastic polymer), or by laminating together different layers of polymer (e.g. elastomeric thermoplastic polymer).

The planar, electrically insulating polymer substrate of the polymer socket comprises perforations coinciding with the back face emitter contacts and back face collector contacts of the back-contact photovoltaic cell that is accepted and electrically connected by the polymer socket comprising the substrate. The perforations are preferably of similar size and shape as the contacts on the back-contact photovoltaic cell accepted by the socket. Preferably, the perforations are between 1 mm and 7 mm in diameter and of round or rectangular shape. In a preferred embodiment, the perforations have diameters that are not more than twice the diameter of the corresponding electrical contacts of the back-contact cell accepted by the socket. The perforations may be formed by drilling, the cutting, laser cutting, molding, etching or other methods know in the art. Preferably, each or nearly every perforation in the socket substrate is aligned over a photovoltaic cell back contact when the socket is positioned on the back face of the cell. Thus, the perforations make it possible to establish an electrical contact between back face emitter contacts and the back face collector contacts of the back-contact cell and the corresponding electrical conductors positioned on the back face of the planar, electrically insulating polymer substrate of each socket. The connection may, for example, be a soldering connection to be made between a conductor and the emitter or collector contact through the perforations. At the same time, the electrical conductors are electrically insulated from the back-contact cell by the planar, electrically insulating polymer substrate of the socket where the polymer substrate is not perforated.

In the case where the electrical contact between back face emitter contacts and the back face collector contacts of the back-contact cell and the electrical conductors positioned on the back face of the planar, electrically insulating polymer substrate is made by soldering connection through the perforations, the soldering may be achieved by methods known in the art of photovoltaics, such as for example induction heating, sonic vibration heating or thermosonic vibration heating, press heating, heated rolls, heated pins or infra-red heating. In the case where soldering is achieved by heated rolls, the rolls are preferably dented such that the dents push each electrical conductor through the perforations of the planar, electrically insulating polymer substrate, such that an electrical contact between the at least one set of linearly arranged back face emitter contacts and back face collector contacts of the back-contact cell and the electrical conductors is achieved. The electrical contact between back face emitter contacts and the back face collector contacts of the back-contact cell and the electrical conductors positioned on the back face of the planar, electrically insulating polymer substrate may also be made by connecting the electrical conductors with the emitter or collector contacts using electrically conductive adhesives through the perforations.

The electrical conductors may be of any electrically conductive material such as for example, copper, iron, aluminum, tin, silver, gold, and alloys thereof. Preferably, the electrical conductors comprise a copper or aluminum core surrounded by an electrically conductive soldering composition. Examples of electrically conductive soldering compositions are tin-, tin-lead-, or tin-lead-silver-based soldering compositions. The electrical conductors are linearly extending electrical conductors, and may be in the form of, for example, a flattened wire or ribbon, round wire, or printed circuit, and preferably are in the form of a flattened ribbon or wire. By linearly extending, it is mean that the electrical conductor extends in a lengthwise direction more than 10 times its width, and preferably more than 20 times its width. Preferably, the ribbons are between 0.8 and 4 mm wide and between 100 um and 250 um thick, and more preferably between 1 and 2.5 mm wide and between 120 and 220 um thick. The cross-sectional area of the wire or ribbon is preferably in the range of 0.04 to 5 mm² and more preferably in the range of 0.1 to 2 mm². Where the electrical conductors comprise a printed circuit line, the circuit may be printed from a conductive metal paste such as a copper, silver or aluminum containing conductive paste that has been screen printed in lines.

The electrical conductors positioned on the back face of the polymer substrates of the sockets are preferably collinear with the at least one set of linearly arranged back face emitter contacts or the at least on set of linearly arranged back face collector contacts of the back-contact cell accepted and electrically connected by each socket, and also with the perforations of the planar polymer substrate coinciding with the at least one set of linearly arranged back face emitter contacts or back face collector contacts. Thus, the at least one set of linearly arranged back face emitter contacts and back face collector contacts can be electrically connected to one of the electrical conductors through the perforations, for example, by soldering or with an electrically conductive adhesive.

The electrical conductors are located on the back face of the planar polymer substrate of each socket, i.e. it is separated, and electrically insulated, from the back-contact photovoltaic cell located on the front face of the polymer substrate by the polymer substrate itself in areas where the polymer substrate is unperforated. The electrical conductor may be held in place on the socket solely by the connections between the conductors and the contacts on the back-contact solar cells accepted by the socket. Alternatively, the at least one electrical conductor may be adhered to the back face of the planar polymer substrate by a suitable adhesive, or it may be adhered to the back face of the planar polymer substrate by heating the electrical conductor to a temperature above the melting temperature of the polymer (e.g. elastomeric thermoplastic polymer) of the planar polymer substrate, pressing the electrical conductor against the back face of the planar polymer substrate until the temperature of the conductor drops below the melting temperature of the polymer of the planar polymer substrate, and releasing the previously applied pressure. The at least one electrical conductor may be heated to a temperature above the melting temperature of the polymer of the planar polymer substrate by methods known in the art of photovoltaic applications, such as for example induction heating, sonic vibration heating or thermosonic vibration heating, press heating, heated rolls, heated pins or infrared heating.

The interconnection of the polymer sockets to form the concatenation by the at least one electrical conductor may be carried out manually or using automated equipment. Suitable equipment for interconnecting the polymer sockets may be a so-called “tabber-stringer” that has been modified to process the planar, electrically insulating polymer substrates of the polymer sockets. Conventionally, tabber-stringers are used to string together photovoltaic cells with frontside and backside electrical contacts, or so-called “H cells”. The tabbing unit generally serves to place and orient the photovoltaic cells, before the stringing unit strings the photovoltaic cells together with electrical conductors that connect frontside contacts of one cell to the backside contacts of an adjacent cell. When a tabber-stringer is used with the back-contact PV cells and polymer substrate sockets described herein, in an additional step, the electrically insulating polymer substrates are placed on top of the oriented photovoltaic cells and oriented such that each polymer substrate socket has columns of perforations coinciding with and aligned over the linearly arranged back face emitter contacts and linearly arranged back face collector contacts of a back-contact solar cell that is to be accepted on the front face of the socket. The orienting of the electrically insulating polymer substrates on top of the oriented photovoltaic cells in the tabber-stringer may be done manually or by an automated alignment mechanism, or by a robot.

In the case where the electrical conductors adhere to the planar, electrically insulating polymer substrate, the tabber-stringer may adhere the electrical conductors to the planar, electrically insulating polymer substrate by heating the conductors to a temperature above the melting temperature of the polymer of the planar polymer substrate and by pressing the electrical conductors against the back face of the planar polymer substrate until the temperature of the conductors drop below the melting temperature of the polymer of the planar polymer substrate, and by then releasing the previously applied pressure.

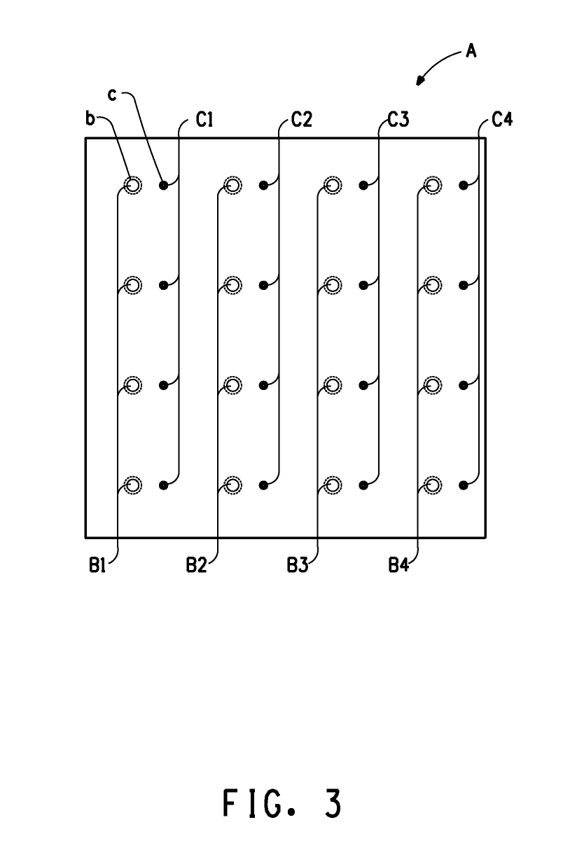

The back-contact cells useful in the present invention may be chosen among MWT cells, BJ cells, IBC cells, EWT cells and other cells having both collector and emitter contacts on the back side of the cell, and are preferably MWT or IBC cells. The back-contact cells may be back-contact cells having the back face emitter contacts and the back face collector contacts coated with an electrically conductive soldering composition. Examples of electrically conductive soldering compositions are tin-, tin-lead-, or tin-lead-silver-based soldering compositions. The back-contact cells of the disclosed photovoltaic modules may be cells having “symmetrical” back-contact cells, i.e. back-contact cells having the same number of linearly arranged back face emitter contact sets and linearly arranged back face collector contact sets. In “symmetrical” back-contact cells, the sets of linearly arranged back face emitter contacts and the sets of linearly arranged back face collector contacts preferably alternate. FIG. 3 shows a symmetrical back-contact cell in which the sets of linearly arranged back face emitter contacts and back face collector contacts alternate, and in which there are the same number of linearly arranged back face emitter contact sets and of linearly arranged back face collector contact sets.

In the case where the planar, electrically insulating polymer substrate of each polymer socket comprises perforations coinciding with the at least one set of linearly arranged back face collector contacts as well as perforations coinciding with the at least one set of linearly arranged back face emitter contacts of the back-contact photovoltaic cell accepted and electrically connected, the perforations coinciding with the set of linearly arranged back face collector contacts of the polymer substrate of one polymer socket may be arranged collinear with the perforations coinciding with a set of linearly arranged back face emitter contacts of the polymer substrate of the adjacent polymer socket. The rotation of the photovoltaic cells by 180° in the plane of the photovoltaic cell with respect to each other has the result that the linearly arranged emitter contact sets of a first photovoltaic cell are aligned, or collinear with the linearly arranged collector contact sets of the adjacent photovoltaic cell, such that they may be electrically connected by at least one electrical conductor that is substantially straight in the direction of concatenation.

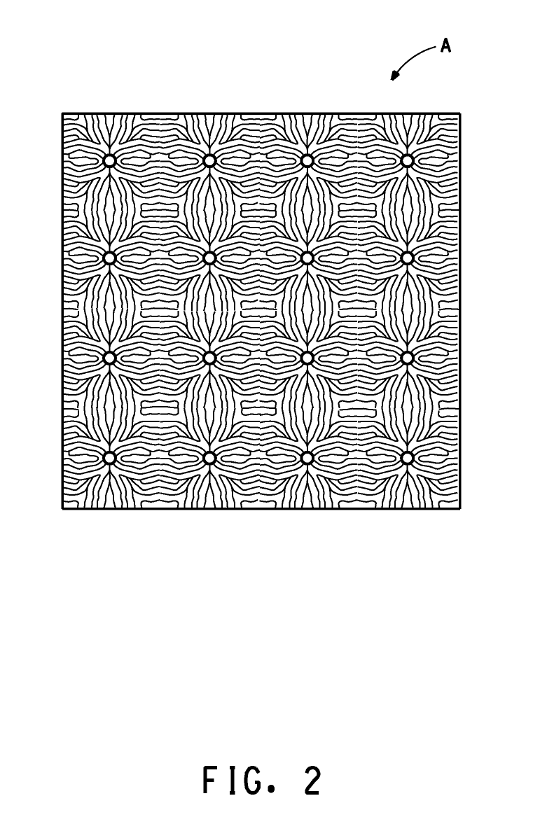

FIG. 2 shows the front face of a MWT photovoltaic cell A. The lines that can be seen on the surface of the MWT back-contact photovoltaic cell are emitter contact lines comprised of a conductive material such as silver. The lines connect to a plurality of spaced electrical vias that can be seen in FIG. 2 and which connect through the photovoltaic cell to back face emitter contacts on the back of the cell.

FIG. 3 shows the back face of a MWT photovoltaic cell A having four sets (B1, B2, B3, B4) of linearly arranged back face emitter contacts b and four sets (C1, C2, C3, C4) of linearly arranged back face collector contacts c.

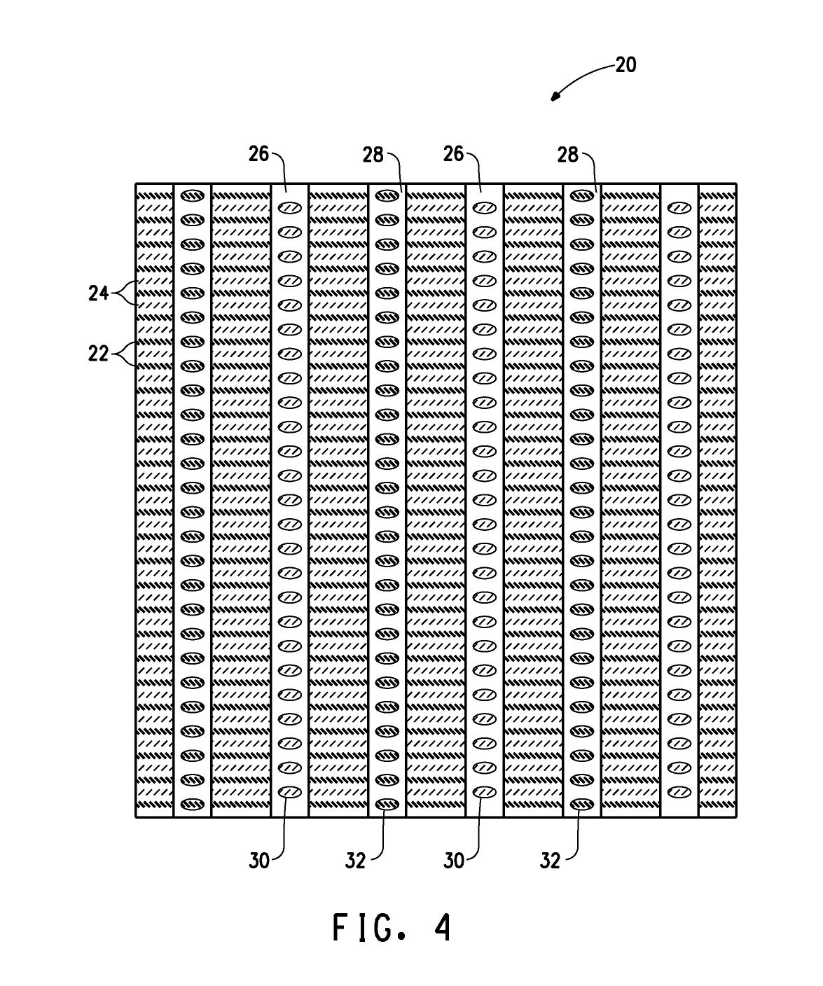

FIG. 4 shows the back face of an IBT photovoltaic cell 20 having alternating interdigitated emitter and collector regions. Emitter conductors 22 alternate with collector conductors 24. The emitter and collector conductors are preferably comprised of electrically conductive metals such as silver, aluminum, tin, and combinations thereof. An electrical insulator 26 or 28 is preferably deposited over the gridlines with openings that expose only one of the polarities. This way, the electrical conductors can be connected only to the exposed contacts 30 or 32 of the desired polarity.

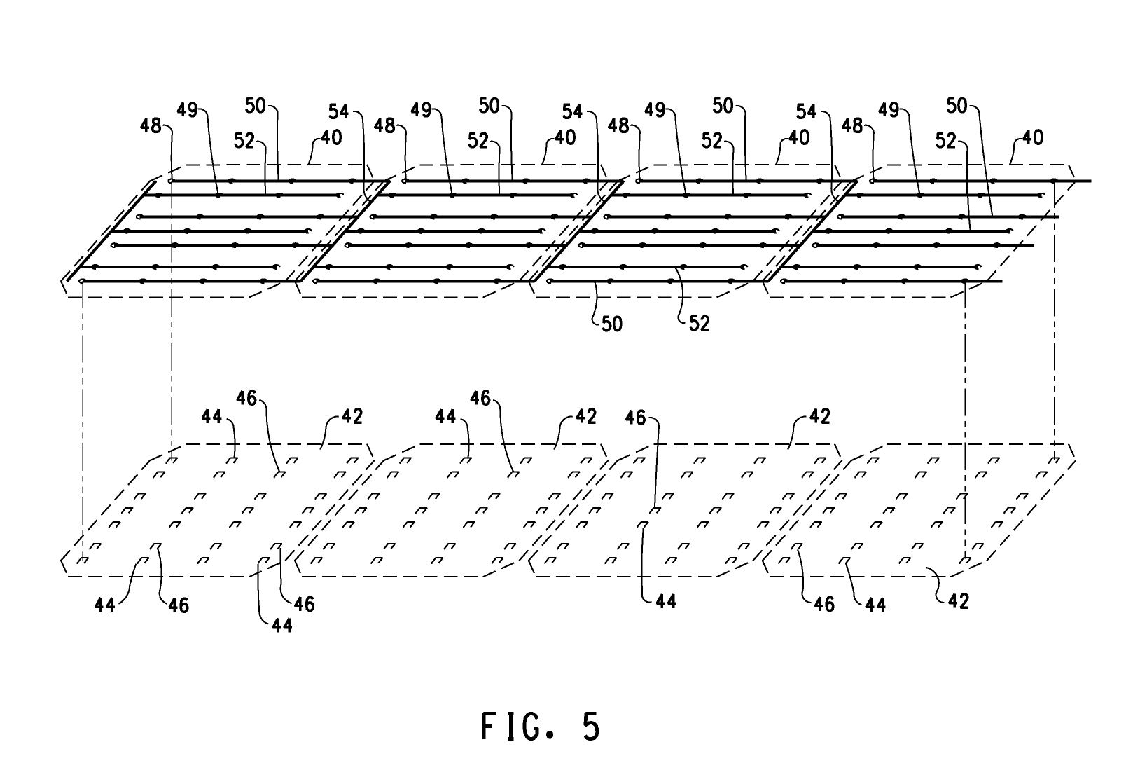

FIG. 5 shows an exploded view of concatenated polymer socket substrates 40 that each accept a line of back-contact photovoltaic cells 42. The back face of the back-contact photovoltaic cells 42 can be seen with linearly arranged emitter contacts 44 and collector contacts 46 on the back face of each cell 42. The cells shown in FIG. 5 each have four columns of linearly arranged emitter contacts 44 and three columns of linearly arranged collector contacts 46. The emitter contacts and collector contacts may be comprised of any electrically conductive material such as for example, silver, copper, iron, aluminum, tin, gold, and alloys thereof. Preferably, the conductors comprise silver. Each contact preferably has an area of about 1 to 25 mm² and a thickness of about 5 to 30 um.

The socket substrates 40 shown in FIG. 5 each accept and electrically connect one of the back contact cells 42. Each socket substrate has a length and width that is the same or substantially similar to the length and width of the corresponding back-contact cell. Each of the socket substrates has multiple columns of perforations or openings 48 and 49. The perforations 48 are linearly arranged in a column with each of the perforations 48 aligned directly over one of the emitter contacts 44. The perforations 49 are linearly arranged in a column with each of the perforations 49 aligned directly over one of the collector contacts 46. Electrical conductors 50 are positioned over the perforations 48 and conductors 52 are positioned over the perforations 49. The conductors may be adhered to the socket substrates 50 or they may be held in place relative to the substrates by the connection of the conductors to the back contacts on the cells 42. The conductors 50 are electrically connected through the perforations 48 to the emitter contacts 44, and the conductors 52 are electrically connected through the perforations 49 to the collector contacts 46. The connections can be made by any of the methods described above, such as by soldering or with an electrically conductive adhesive. The conductors 50 on one socket substrate each connect to an electrically conductive cross connector 54 which in turn is connected to the conductors 52 on an adjacent socket. The cross connector electrical conductor 54 is shown in FIG. 5 as being located on the adjacent socket, but it may also alternatively be located on the same socket as the conductors 50. Thus, the emitter contacts 44 on one cell electrically connect to the electrical conductors 50 on one socket substrate, which connect to the cross connector electrical conductor 54, which electrically connects to the electrical conductors 52 on an adjacent socket substrate which electrically connect to the collector contacts 46 on the adjacent cell.

FIG. 5 shows just one portion of one column of back-contact solar cells, it is contemplated that a photovoltaic module will comprise multiple columns of multiple back contact cells with as many as 40 to 200 series connected cells and corresponding sockets in a module.

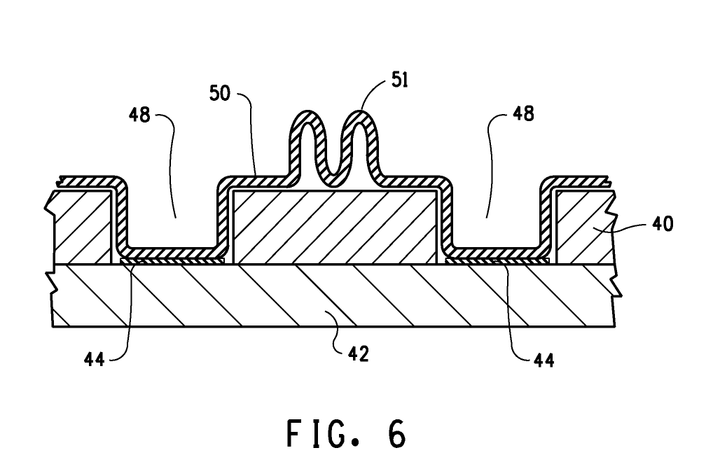

FIG. 6 shows a cross section of a portion of the module shown in FIG. 5 with the substrate of the socket 40 positioned on the back face of the back-contact cell 42. Emitter contacts 44 are shown soldered to the conductor 50 in several of the socket openings 48. The conductor 50 is preferably a metal ribbon as described above. The ribbon is shown with one or multiple kinks 51 that can be inserted into the conductor 50 in order to relieve cell stress when the ribbons are soldered to the cell contacts. The conductor 50 is shown on, but not adhered to, the substrate of the socket 40, but the conductor could alternatively be adhered to the socket 40 by an adhesive or by softening the polymer substrate material of the socket when the conductor is applied to the socket or when the conductor is adhered to the emitter contacts 44. The conductors 52 are attached to the collector contacts 46 in the same manner.

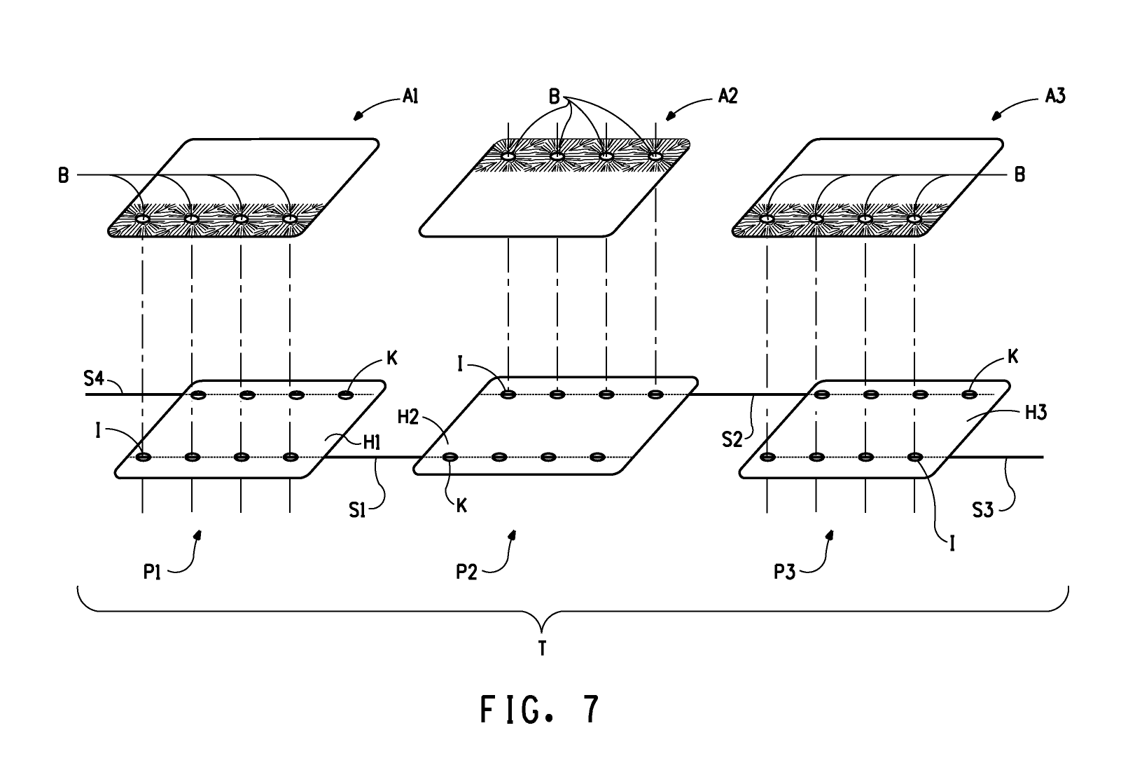

FIG. 7 shows an alternative embodiment with a plurality of MINT photovoltaic cells (A1, A2, A3) of a back-contact photovoltaic module. A plurality of polymeric sockets (P1, P2, P3) comprising planar, electrically insulating polymer substrates (H1, H2, H3) are provided on the back face of each of the MWT cells. The polymeric sockets have perforations I coinciding with a set of linearly arranged back face emitter contacts B of the MWT photovoltaic cells to be accepted by the corresponding sockets. The polymeric sockets have perforations K corresponding with a set of linearly arranged back face collector contacts (not shown) of the MWT photovoltaic cells (A1, A2, A3) accepted by the corresponding sockets.

The polymer socket substrates and MWT cells are interconnected by the electrical conductors (S1, S2, S3, S4) to form a concatenation T of interconnected polymer sockets. The electrical conductors are preferably metal ribbons or wires as described above. The back face emitter contacts of a first cell A1 are electrically connected to the conductor S1 through the perforations I in the polymer substrate. The back face emitter contacts of a first cell A1 are electrically connected to the back face collector contacts of the adjacent cell A2 via the conductor S1. The conductor is collinear with the perforations I coinciding with the set of linearly arranged back face emitter contacts of the MWT cells and the perforations K coinciding with the set of linearly arranged back face collector contacts of the MWT photovoltaic cell accepted and electrically connected by the adjacent polymer socket H2. For illustrative purposes, FIG. 7 shows photovoltaic MWT cells with just one row of emitter contacts and just one row of collector contacts, but it is contemplated that back-contact photovoltaic cells with multiple rows of emitter contacts and collector contacts, like the cell shown in FIG. 3, can be electrically connected with polymeric sockets having a corresponding number of electrical conductors. The conductors may be electrically connected to the emitter and collector contacts of the back-contact photovoltaic cells in the manners described above with regard to FIG. 6.

The photovoltaic module of the present invention comprises a front sheet. The function of the front sheet is to provide a transparent protective layer that will allow incident light (e.g., sunlight) to reach the front face of the back-contact photovoltaic cells in the module. In general, the front sheet material may be of any material that provides protection against the elements for the module while also providing transparency to the incident light. The front sheet may be made of a rigid material, such as a glass, polycarbonate, acrylate polymer such as polymethylmethacrylate (PMMA) material, or a more flexible material, such as a fluoropolymer like for example polyvinyl fluoride (PVF), a polyvinylidene fluoride (PVDF), an ethylene tetrafluorethylene (ETFE) polymer, a perfluoroalkoxy vinyl polymer (PFA), a fluorinated ethylene propylene copolymer (FEP) of tetrafluoroethylene (TFE) and hexafluoropropylene (HFP), or a combination thereof. The front sheet may be a single layer of material, or may include more than one layer of the same or different materials.

The photovoltaic module according to the present invention also comprises a front encapsulant layer. The front encapsulant layer in the photovoltaic module according to the present invention may comprise any material as is conventional in the art of photovoltaic modules, i.e. the front encapsulant layer may comprise various transparent polymeric materials. The thickness of the front encapsulant layer may be in the range of, for example, 100 to 2000 μm, preferably of from 200 to 1000 μm, as is conventional for front encapsulant layers in photovoltaic modules.

The front encapsulant layer of the photovoltaic module according to the present invention is located adjacent to and between the front sheet and the front face of the back-contact photovoltaic cells. The front encapsulant layer is designed to encapsulate and further protect the front face of the back-contact photovoltaic cells from environmental degradation and mechanical damage, but at the same time is required to have excellent transparency that allows a maximum of incident light to reach the front face of the photoactive cells, and also bonds the photoactive cells to the front sheet.

Preferably, the front encapsulant layer comprises ethylene vinyl acetate copolymer, polyvinyl butyral, ethylene alkyl (meth)acrylate copolymer, thermoplastic polyurethane, ionomer, and/or any combinations thereof. More preferably, the front encapsulant layer comprises an ionomer, and preferably comprises a blend of a first ionomer and a second ionomer different from the first ionomer or a blend of a first ionomer and a non-neutralized copolymer of ethylene and (meth)acrylic acid. In the case where the front encapsulant layer comprises an ionomer or a blend of ionomers, the ionomers are preferably chosen from ionomers that comprise from 8 wt % to 25 wt % of an ethylenically unsaturated, C3 to C8 carboxylic acid, and optionally comprise from 10 wt % to 20 wt % of an alkyl acrylate, based on the total weight of the ionomer.

Suitable ionomers and blends of a first ionomer and a second ionomer are further described in European patent EP1781735, which is hereby incorporated by reference. In the case where the front encapsulant layer comprises a blend of a first ionomer and a non-neutralized copolymer of ethylene and (meth)acrylic acid, the non-neutralized copolymer of ethylene and (meth)acrylic acid preferably comprises from 2 to 15 weight percent, more preferably from 2 to 9 weight percent of (meth)acrylic acid, based on the total weight of the non neutralized copolymer of ethylene and (meth)acrylic acid.

The front encapsulant layer can include more than one layer of encapsulant material, wherein each layer may include the same encapsulant material or a different encapsulant material from the other layer(s). The front encapsulant layer may further comprise UV stabilization additives to prevent UV degradation of the encapsulant, but such additives are preferably not included in the front encapsulant layer in order to allow as much light, including UV, as possible to go through the encapsulant layer.

The module according to the present invention comprises a plurality of concatenated polymer sockets, in which each polymer socket accepts and electrically connects a back-contact photovoltaic cell as described above. Back-contact cells of the disclosed embodiments include MWT cells, BJ cells, IBC cells and EWT cells, and are preferably MWT or IBC cells. The back-contact cells are back-contact cells having the back face emitter contacts and the back face collector contacts as described above.

The photovoltaic module according to the invention can optionally comprise a back encapsulant layer, and preferably it comprises a back encapsulant layer. The optional back encapsulant layer in the photovoltaic module according to the present invention may comprise any material as is conventional in the art of photovoltaic modules, Le. the optional back encapsulant layer may comprise various polymeric materials. The thickness of the optional back encapsulant layer may be in the range of, for example, 100 to 2000 μm, preferably of from 200 to 1000 μm, as is conventional for back encapsulant layers in photovoltaic modules. Preferably, the optional back encapsulant layer comprises polymer like those described above for the front encapsulant layer such as ethylene vinyl acetate copolymer, polyvinyl butyral, ethylene alkyl (meth)acrylate copolymer, thermoplastic polyurethane, ionomer, and/or any combinations thereof.

The back sheet in the photovoltaic module according to the present invention may be any back sheet as is conventional in the art of photovoltaic modules, i.e. the back sheet is formed from any rigid material, and the thickness of the back sheet may be in the range of, for example, 500 μm to 2 cm, as is conventional for back sheets of photovoltaic modules. The back sheet can be made of a rigid material, such as glass, polyamide, polycarbonate, polyethylene terephthalate, epoxy resin, acrylate polymer such as polymethylmethacrylate (PMMA), glass fiber reinforced polyamide or polyester, carbon fiber reinforced polymer such as any kind of carbon fiber reinforced polyamide like polyamide 34, 6, 66, 6.66, 6T, 610, 10, 11, 12, glass reinforced polyester such as PET, PEN, PETG, asbestos, and ceramic. In general, the back sheet material may be any material that provides electrical insulation and electrical shock protection. The back sheet may be a single layer of material, or may include more than one layer of material. In the case where the back sheet of the module includes more than one layer of material, it preferably includes a laminate consisting of one or more layers of polyethylene terephthalate sandwiched between polyvinyl fluoride (PVF) layers.

The present invention further provides for a process for the manufacture of a photovoltaic module comprising the steps of assembling a stack by placing a front encapsulant layer on a front sheet, placing a plurality of back-contact cells on the encapsulant layer with the front face of the cells on the front encapsulant layer, placing a plurality of polymer socket substrates on the back face of the back contact cells, where the socket substrates have perforations that are aligned over each of the emitter and collector contacts of the cell, positioning a plurality of electrical conductors on the back face of each socket substrate and connecting each substrate to a line of emitter contact or a line of collectors contact on the cell back face though the perforations in the socket substrate, interconnecting the conductors on adjacent sockets, placing an optional back encapsulant layer over the back face of the sockets, and placing a backsheet over the back face of the sockets and the optional back encapsulant layer. In an alternative process for the manufacture of the photovoltaic module, the stack can be assembled by placing an optional back encapsulant layer on a back sheet, placing a plurality of concatenated polymer sockets, each polymer socket having accepted and electrically connected a back-contact photovoltaic cell, on top of the optional back encapsulant layer, placing a front encapsulant layer on top of the back-contact photovoltaic cells and then placing a front sheet on top of the front encapsulant layer. The stack assembly can be carried out manually or automatically on an assembling device such as for example a positioning robot. In the process for the manufacture of the photovoltaic module, the step of assembling a stack may be carried out in advance outside the laminating device or may be carried out inside (in-situ) the laminating device, and is preferably carried out inside the laminating device to reduce production cycle times.

The so assembled stack is then consolidated in a laminating device by heating the stack to a temperature of from 100 to 225° C. and subjecting the heated stack to a mechanical pressure in a direction perpendicular to the plane of the stack and decreasing the ambient pressure in the laminating device to 300 to 1200 mbar, and then cooling the stack to ambient temperature and releasing the mechanical pressure and reestablishing atmospheric pressure in the laminating device. In the case of modules made with MWT cells, the back-contact photovoltaic cells accepted and electrically connected by adjacent polymer sockets may be rotated by 180° with respect to each other. In case no back encapsulant layer is placed on the back sheet, the back sheer is placed directly on the plurality of concatenated polymer sockets. A laminating device useful in the automatic process for manufacturing the photovoltaic module can be a heat press, for example.

In the process for the manufacture of the photovoltaic module, the step of consolidating the assembled stack in a laminating device is achieved by heating of the stack in the laminating device by, for example, heating the top, lower, or both, platen of the laminating device. The stack is brought to a temperature of from 100 to 225° C., from 100 to 180° C., and in particular of from 120 In 170° C. and more particularly of from 130 to 150° C. Such temperature allows the front and optional back encapsulants to soften, flow around and adhere to the concatenated polymer sockets, each polymer socket having accepted and electrically connected a back-contact photovoltaic cell. Within the limits of the above temperature ranges, the person skilled in the art will choose a temperature setting for the laminating device such that it is high enough to soften or melt the front and optional back encapsulants, but low enough so as to prevent the polymer sockets from softening or melting.

In the process for the manufacture of the photovoltaic module, the step of consolidating the assembled stack in a laminating device is further achieved by subjecting the stack to mechanical pressure perpendicular to the plane of the stack, which pressure may be exerted via the platen of the laminating device.

In the process for the manufacture of the photovoltaic module, the step of consolidating the assembled stack in a laminating device is further achieved by decreasing the ambient pressure in the laminating device to 100 to 1200 mbar or 300 to 1200 mbar, in particular to 500 to 1000 mbar and more particularly 600 to 900 mbar. Decreasing the ambient pressure in the laminating device facilitates the removal of air pockets that may have eventually formed between the different layers of the stack during the step of assembling the stack.

In the process for the manufacture of the photovoltaic module, the step of consolidating the assembled stack in a laminating device is finished by cooling the stack to ambient temperature and by releasing the mechanical pressure and reestablishing atmospheric pressure in the laminating device.

What is claimed is:

1. A photovoltaic module comprising:
a. a front sheet,
b. a front encapsulant layer having opposite first and second sides, the first side of said front encapsulant layer being adhered to said front sheet,
c. a plurality of back-contact photovoltaic cells each having a front face and a back face, each back-contact photovoltaic cell having on its back face at least one set of linearly arranged back face emitter contacts and at least one set of linearly arranged back face collector contacts, the front face of each of said back-contact photovoltaic cells being adhered to the second side of said front encapsulant layer,
d. a plurality of concatenated polymer sockets arranged in one or more rows, each polymer socket having accepted and electrically connected one of said back-contact photovoltaic cells,
e. a back sheet adhered over said plurality of concatenated polymer sockets,
wherein each polymer socket comprises
i. a planar, electrically insulating polymer substrate, said substrate having a front face and back face on opposite sides of the substrate, the front face being on the side of the substrate on which the back-contact photovoltaic cell is accepted by the polymer socket, said polymer substrate having a shape, length and width that substantially corresponds to the shape, length and width of the back-contact photovoltaic cell accepted by the socket, said polymer socket having columns of linearly arranged perforations wherein the perforations of each column of perforations coincide with and are aligned over corresponding emitter contacts of the at least one set of linearly arranged back face emitter contacts or corresponding collector contacts of the at least one set of linearly arranged back face collector contacts of the back-contact photovoltaic cell accepted by the polymer socket,
ii. a plurality of linearly extending electrical conductors positioned on the back face of the polymer substrate, each of said electrical conductors being collinear with a column of the perforations in the polymer substrate and coinciding with one of the at least one set of linearly arranged back face emitter contacts or one of the at least one set of linearly arranged back face collector contacts of the back-contact photovoltaic cell accepted and electrically connected by the socket, the electrical conductors each being connected to emitter contacts or collector contacts of the back-contact photovoltaic cell accepted and electrically connected by the socket, and
wherein each back-contact photovoltaic cell of the module is accepted by a separate socket, and the sockets are arranged in rows, and the electrical conductors of each polymer socket that are connected to emitter contacts of the back-contact photovoltaic cell accepted by the socket are electrically connected to an electrical conductor of an adjacent socket in the row of sockets which electrical conductor of the adjacent socket is connected to collector contacts of the back-contact photovoltaic cell accepted by the adjacent socket.

2. The photovoltaic module according to claim 1, wherein the planar polymer substrate comprises of at least one elastomeric thermoplastic polymer.

3. The photovoltaic module according to claim 2, wherein the at least one elastomeric thermoplastic polymer is a polyester polyether copolymer.

4. The photovoltaic module according to claim 1, wherein the back-contact photovoltaic cells accepted by adjacent polymer sockets in each row of sockets are rotated by 180° with respect to each other.

5. The photovoltaic module according to claim 1, wherein said electrical conductors of each polymer socket are adhered to the back face of polymer substrate of the polymer socket.

6. The photovoltaic module according to claim 1, wherein the back sheet is adhered to said plurality of concatenated polymer sockets by a back encapsulant layer disposed between said back sheet and said plurality of concatenated polymer sockets.

7. The photovoltaic module according to claim 1 wherein each of the perforations in the the polymer substrate of the socket are each aligned over an emitter or collector contact on the photovoltaic cell accepted by the socket, and the diameter of each perforation is not more than two times the diameter of the contact with which the perforation is aligned.

8. The photovoltaic module according to claim 1 wherein the polymer substrate of each socket has edges that extend no more than 5 mm beyond the edges of the back-contact photovoltaic cell accepted and electrically connected by the polymer socket.

9. The photovoltaic module according to claim 8 wherein the polymer substrate of each socket has edges that extend no more than 2 mm beyond the edges of the back-contact photovoltaic cell accepted and electrically connected by the polymer socket.

10. The photovoltaic module according to claim 8 wherein the polymer substrate has edges that extend at least 0.5 mm beyond the edges of the back-contact photovoltaic cell accepted and electrically connected by the polymer socket.

11. The photovoltaic module according to claim 1 wherein each of the electrical conductors of a socket that are connected to emitter contacts of the back-contact photovoltaic cell accepted by the socket are electrically connected to each other by a cross connector electrical conductor, and wherein each of the electrical conductors of an adjacent socket in the row of sockets is electrically connected to said cross connector electrical conductor.

12. The photovoltaic module according to claim 1 wherein the conductors on the sockets are metal ribbons, and at least one conductor on each of the sockets is a kinked ribbon.

13. A process for the manufacture of a photovoltaic module comprising the steps of:
a. providing a front encapsulant layer on a front sheet;
b. providing a plurality of back-contact photovoltaic cells each having a front face and a back face, and each having at least one set of linearly arranged back face emitter contacts and at least one set of linearly arranged back face collector contacts on the back face of the back-contact photovoltaic cells, and positioning the front face of said back-contact photovoltaic cells in rows on the front encapsulant layer:
c. providing a plurality of polymer sockets each comprising a planar, electrically insulating polymer substrate, said substrate having a front face and back face on opposite sides of the substrate, the front face being positioned against the back face of one of the back-contact photovoltaic cells, said polymer substrate having a shape, length and width that substantially corresponds to the shape, length and width of the back-contact photovoltaic cell on which the socket is positioned, wherein a separate polymer socket is positioned on each back-contact cell of the module, each of said polymer sockets having columns of linearly arranged perforations wherein the perforations of each column of perforations coincides with and are aligned over corresponding emitter contacts of the at least one set of linearly arranged back face emitter contacts or corresponding collector contacts of the at least one set of linearly arranged back face collector contacts of the back-contact photovoltaic cell on which the polymer socket is positioned,
d. positioning a plurality of linearly extending electrical conductors on the back face of the polymer substrates, each of said electrical conductors being collinear with a column of the perforations in the polymer substrate and coinciding with one of the at least one set of linearly arranged back face emitter contacts or one of the at least on set of linearly arranged back face collector contact of the back-contact photovoltaic cell on which the socket is positioned, and connecting each electrical conductor to emitter contacts of the at least one set of emitter contacts or the collector contacts of the at least one set of collector contacts of the back-contact photovoltaic cell on which the socket is positioned;
e. connecting the electrical conductors of polymer sockets that are connected to emitter contacts of corresponding back-contact photovoltaic cells to electrical conductors of an adjacent socket positioned on an adjacent back-contact photovoltaic cell in the row of cells which electrical conductor of the adjacent socket is connected to collector contacts of the corresponding back-contact photovoltaic cell;
f. providing a back sheet over the electrically connected polymer sockets and electrically connected back-contact photovoltaic cells;
g. consolidating the front sheet, front encapsulant layer, back-contact cells, sockets, and back sheet as a stack in a laminating device by
i. heating the stack to a temperature of from 100 to 225° C.,
ii. subjecting the heated stack to a mechanical pressure in a direction perpendicular to the plane of the stack and decreasing the ambient pressure in the laminating device to 300 to 1200 mbar, and
iii. cooling the stack to ambient temperature and releasing the mechanical pressure and reestablishing atmospheric pressure in the laminating device.

14. The process for the manufacture of a photovoltaic module of claim 13, wherein the back sheet is adhered to said polymer sockets by a back encapsulant layer disposed between said back sheet and said polymer sockets.

15. The process according to claim 13, wherein tabber-stringer automated equipment is used to electrically interconnect adjacent polymer sockets and the back-contact cells on which the polymer sockets are positioned through the plurality of electrical conductors positioned on the polymer sockets.
